(19) United States
(12) Patent Application Publication
(10) Pub. No.: US 2025/0331125 A1
(43) Pub. Date: Oct. 23, 2025

(54) ELECTRONICS PACKAGING ASSEMBLY FOR FACILITATING HEAT TRANSFER

(71) Applicant: Cummins Power Generation Inc., Minneapolis, MN (US)

(72) Inventors: Ikenna Oguguo, Canterbury (GB); Lane Lester Woodland, Eden Prairie, MN (US); Adam James Bower, Minneapolis, MN (US); Nicholas William Shatek, Shoreview, MN (US); Steve N. Seidlitz, Sunfish Lake, MN (US); Wangwei Zhou, Shoreview, MN (US); Joel N. Robinson, St. Paul, MN (US); Pushkar U. Vaidya, Blaine, MN (US); Subbarao Dakshina Murthy Bellur, Minneapolis, MN (US)

(73) Assignee: Cummins Power Generation Inc., Minneapolis, MN (US)

(21) Appl. No.: 18/870,192

(22) PCT Filed: May 31, 2023
(86) PCT No.: PCT/US2023/024010

§ 371 Date: Nov. 27, 2024

Related U.S. Application Data
(60) Provisional application No. 63/347,371, filed on May 31, 2022.

(51) Int. Cl. H05K 7/20

(52) U.S. Cl. CPC H05K 7/20145; H05K 7/20163; H05K 7/20172

(57) ABSTRACT

An electronics packaging assembly configured to facilitate heat transfer includes a housing having an electronics compartment configured to house at least one electronic component therein. The electronics packaging assembly also includes a cooling system. The cooling system extends from a first side of the housing to a second side of the housing and includes an air duct defining an air channel for air flow, an air duct inlet coupled to the first side of the housing, an air duct outlet coupled to the second side of the housing, and a plurality of fins exposed from the housing. A first portion of the electronics compartment is coupled to a top surface of the cooling system and a second portion is coupled to a bottom surface. The cooling system dissipates heat from both portions of the electronics compartment coupled to the cooling system.

### CROSS REFERENCES TO RELATED APPLICATIONS

The present application claims priority to U.S. Provisional Patent Application No. 63/347,371, titled “Electronics Packaging Assembly, Method of Cooling an Electronics Packaging System and Method of Manufacture Thereof,” filed May 31, 2022, which is incorporated herein by reference in its entirety.

### TECHNICAL FIELD

The present disclosure relates generally to electronics packaging assemblies, and to methods of cooling and of manufacture of such assemblies.

### BACKGROUND

Power generators are a mobile power source that may be configured for a variety of purposes. For example, during particular operations, power generators are configured to meet a variety of design requirements including mass and noise limits, power and cooling performance efficiency, and electromagnetic, temperature, and structural resiliency. Changing consumer demands and increased fuel supply chain constraints have led to a demand for mobile power generators utilizing renewable power sources. Further, as mobile power generators are designed to meet stricter operating requirements and consumer demands, mobile power generators also are designed to continue to efficiently cool electronic components therein to prevent overheating and/or damage to electronic components.

Cooling systems which conduct heat from only a single direction are susceptible to have more limited reductions in temperature, thus impacting whether cooling efficiency requirements are met.

### SUMMARY

The present disclosure relates to techniques for providing and cooling an electronics packaging assembly using a cooling system therefor. In particular, such techniques achieve mass, volume, and noise specifications, achieve electromagnetic, temperature, and structural resiliency, and provide for efficient cooling of an electronics compartment disposed within the electronics packaging assembly. Further, the present disclosure allows for multidirectional cooling of the electronics compartment via the cooling system of the electronics packaging assembly to facilitate heat transfer, including under harsh operating and environmental conditions.

In at least one embodiment, an electronics packaging assembly configured to facilitate heat transfer includes a housing including an electronics compartment configured to house at least one electronic component therein; and a cooling system extending from a first side of the housing to a second side of the housing opposite the first side, the cooling system including an air duct defining an air channel for air flow, an air duct inlet coupled to the first side of the housing, an air duct outlet coupled to the second side of the housing, and a plurality of fins exposed from the housing, the electronics compartment being configured such that a first portion of the electronics compartment is coupled to a top surface of the cooling system and a second portion of the electronics compartment is coupled to a bottom surface of the cooling system, and the cooling system being configured to facilitate heat transfer by dissipating heat from both the first portion of the electronics compartment coupled to the top surface of the cooling system and the second portion coupled to the bottom surface of the cooling system.

In some embodiments, the housing includes an outer frame and an inner frame suspended within the outer frame. The air duct inlet is coupled to the outer frame at the first side and the air duct outlet is coupled to the outer frame at the second side, respectively, and at least a portion of the electronics compartment is disposed within the inner frame. In some embodiments, the electronics packaging assembly further includes a plurality of isolators disposed between the inner frame and the outer frame configured to suspend the inner frame within the outer frame and to reduce vibration of the electronics packaging assembly.

In some embodiments, at least one of the air duct inlet or the air duct outlet includes an inlet fan or an outlet fan, respectively, to allow air flow through the air channel. In some embodiments, the cooling system further comprises a circulation fan disposed within the electronics compartment. In some embodiments, an operating temperature range of the electronics packaging assembly is approximately −25° F. to 125° F., inclusive.

In some embodiments, a noise level of the electronics packaging assembly is maintained below an audible threshold within an area extending approximately twenty meters away from and surrounding the electronics packaging assembly. In some embodiments, the air duct includes a non-uniform surface configured to increase turbulence of the air flow. In some embodiments, the air duct is a copper heat pipe inlay. In some embodiments, the cooling system includes thermally conductive encapsulants disposed on a surface of the air duct.

In some embodiments, the first portion of the electronics compartment includes a direct current transformer and a first voltage direct current power stage, and the second portion of the electronics compartment includes a second voltage direct current power stage higher in voltage than the first voltage direct current power stage and a direct current to alternating current inverter.

In at least one embodiment, a method for cooling an electronics packaging assembly is provided. The electronics packaging assembly includes a housing including an electronics compartment configured to house at least one electronic component therein; and a cooling system extending from a first side of the housing to a second side of the housing opposite the first side, the cooling system including an air duct defining an air channel for air flow, an air duct inlet coupled to the first side of the housing, an air duct outlet coupled to the second side of the housing, and a plurality of fins exposed from the housing, a first portion of the electronics compartment coupled to a top surface of the cooling system and a second portion coupled to a bottom surface of the cooling system. The method includes transferring heat from the first portion of the electronics compartment to the cooling system; transferring heat from the second portion of the electronics compartment coupled to the bottom surface of the cooling system to the cooling system; allowing air flow through the air channel; and dissipating heat, by the plurality of fins, from the electronics packaging assembly to an exterior environment via the plurality of fins.

In some embodiments, the method further includes forcing air to flow through the air channel, using at least one of an inlet fan or an outlet fan coupled to the air duct inlet or the air duct outlet, respectively. In some embodiments, the method further includes circulating air within the electronics compartment using a circulation fan disposed within the electronics compartments. In some embodiments, the method further includes increasing turbulence of the air flow along at least a portion of the air duct.

In at least one embodiment, a method for manufacturing an electronics packaging assembly is provided. The electronics packaging assembly includes a housing including an electronics compartment configured to house at least one electronic component therein; and a cooling system including an air duct, an air duct inlet, an air duct outlet, and a plurality of fins. The method includes: disposing the cooling system within the housing such that the air duct extends from a first side of the housing to a second side of the housing opposite the first side; exposing the air duct inlet and the air duct outlet from the housing to define an air channel through the air duct; coupling a first portion of the electronics compartment to a top surface of the cooling system and a second portion to a bottom surface of the cooling system; and exposing the plurality of fins from the housing.

In some embodiments, the method further includes coupling at least one of an inlet fan or an outlet fan to at least one of the air duct inlet or the air duct outlet, respectively. In some embodiments, the method further includes disposing a circulation fan within the electronics compartment to provide air circulation within the electronics compartment.

In some embodiments, the method further includes adjusting a direct current power supply by a direct current transformer and providing a first direct current power stage in the first portion of the electronics compartment coupled to the top surface of the cooling system; and generating a second voltage direct current power stage higher in voltage than the first direct current power stage and converting a direct current to alternating current by an inverter in the second portion of the electronics compartment coupled to the bottom surface of the cooling system. In some embodiments, the method further includes coupling an electromagnetic interference (EMI) filter assembly to the housing, the EMI filter assembly being configured to resist electromagnetic interference.

It is to be understood that both the foregoing general description and the following detailed description are exemplary and explanatory only, and are not restrictive of the present teachings.

### BRIEF DESCRIPTION OF THE DRAWINGS

The disclosure will become more fully understood from the following detailed description, taken in conjunction with the accompanying figures, wherein like reference numerals refer to like elements unless otherwise indicated, in which:

FIG. 1 is a perspective view of a mobile power source system including an electronics packaging assembly, according to an exemplary embodiment;

FIG. 2 is a perspective view of the mobile power source system of FIG. 1 configured with a 5 kilowatt generator;

FIG. 3 is a perspective view of the mobile power source system of FIG. 1 configured with a 10 kilowatt generator;

FIG. 4 is a perspective view of the mobile power source system of FIG. 1 configured with a 15 kilowatt generator;

FIG. 5 is a block diagram of the mobile power source system including the electronics packaging assembly, according to an exemplary embodiment;

FIG. 6 is a perspective view of the electronics packaging assembly including a housing, according to an exemplary embodiment;

FIG. 7 is another perspective view of the electronics packaging assembly including the housing, according to an exemplary embodiment;

FIG. 8 is a schematic diagram of the electronics packaging assembly, according to an exemplary embodiment;

FIG. 9 is a cross-sectional side view of the electronics packaging assembly taken along Plane A-A of FIG. 6, according to an exemplary embodiment;

FIG. 10 is another cross-sectional side view of the electronics packaging assembly taken along Plane A-A of FIG. 6, according to an exemplary embodiment;

FIG. 11 is a bottom perspective view of the electronics packaging assembly without an outer frame, according to an exemplary embodiment;

FIG. 12 is a top perspective view of the electronics packaging assembly of FIG. 8, according to an exemplary embodiment;

FIG. 13 is a flowchart illustrating a method for cooling the electronics packaging assembly, according to an exemplary embodiment; and

FIG. 14 is a flowchart illustrating a method for manufacturing the electronics packaging assembly, according to an exemplary embodiment.

### DETAILED DESCRIPTION

Following below are more detailed descriptions of various concepts related to, and implementations of, methods, apparatuses, and for providing a cooling system for an electronics packaging assembly. The various concepts introduced above and discussed in greater detail below may be implemented in any of a number of ways, as the described concepts are not limited to any particular manner of implementation. Examples of specific implementations and applications are provided primarily for illustrative purposes.

Various embodiments disclosed herein provide for at least one exemplary embodiment of an electronics packaging assembly configured to facilitate heat transfer using a cooling system. As explained in more detail herein, the electronics packaging assembly includes the cooling system to cool an electronics compartment disposed within a housing of the electronics packaging assembly. Such exemplary embodiments are particularly advantageous as they can achieve more efficient cooling of the electronics packaging assembly under harsh environmental and operating conditions. Further, unlike other configurations of cooling systems that only conduct heat from a single direction, the cooling system of the present disclosure can conduct heat from more than one direction, thereby increasing cooling efficiency.

Implementations described herein are related to a cooling system for an electronics packaging assembly. The electronics packaging assembly includes a housing including an electronics compartment configured to house at least one electronic component therein. The electronics packaging assembly also includes a cooling system extending from a first side of the housing to a second side of the housing opposite the first side. The cooling system includes an air duct defining an air channel for air flow, an air duct inlet coupled to the first side of the housing, an air duct outlet coupled to the second side of the housing, and a plurality of fins exposed from the housing. A first portion of the electronics compartment is coupled to a top surface of the cooling system and a second other portion is coupled to a bottom surface of the cooling system. Further, the cooling system facilitates heat transfer by dissipating heat from both the first portion of the electronics compartment coupled to the top surface of the cooling system and the second portion coupled to the bottom surface of the cooling system.

The present disclosure provides for at least one exemplary embodiment of an electronics packaging assembly 100 configured to facilitate heat transfer using a cooling system 126. Although the following discussion describes embodiments of the electronics packaging assembly 100 as it relates to mobile power generators, the electronics packaging assembly 100 and the cooling system 126 thereof are not so limited. Rather, the electronics packaging assembly 100 and/or the cooling system 126 may be configured to cool electronic components of, for example, a vehicle, construction equipment, farming equipment, etc.

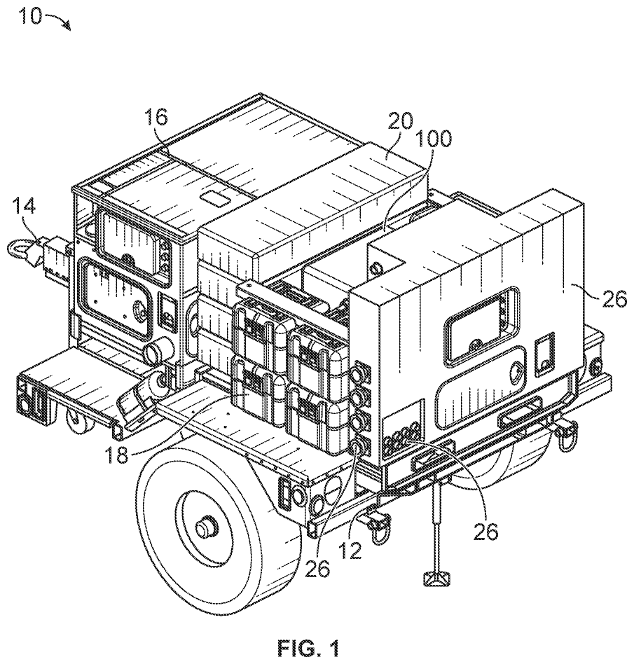

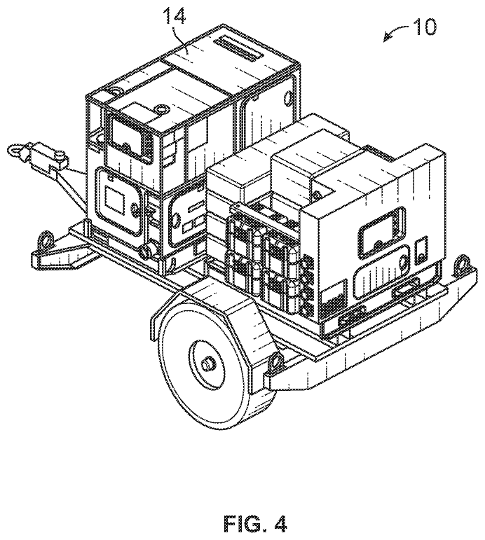

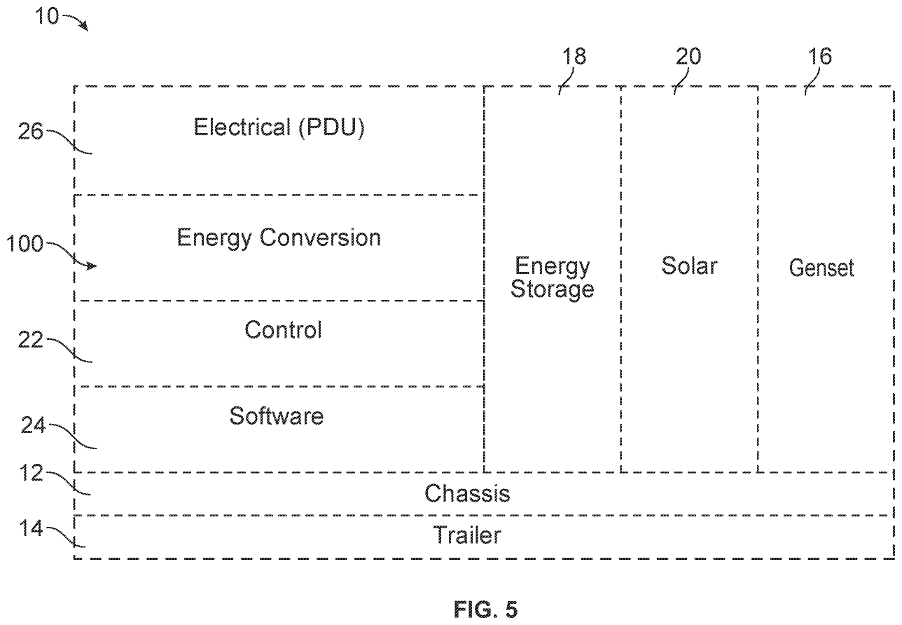

Referring to the figures generally, FIGS. 1-12 depict the electronics packaging assembly 100 of a mobile power source system 10. More particularly, as described below, FIGS. 5-12 collectively depict a cooling system 126 of the electronics packaging assembly 100. The electronics packaging assembly 100 is configured to facilitate heat transfer and includes a housing 110 having an electronics compartment 124 configured to house at least one electronic component therein; and a cooling system 126 extending from a first side 116 of the housing 110 to a second side 118 of the housing 110 opposite the first side 116. The electronics compartment 124 can house the at least one electronic component within walls such as the inner frame 120.

The cooling system 126 includes an air duct 128 defining an air channel 130 for air flow, an air duct inlet 132 coupled to the first side 116 of the housing 110, and an air duct outlet 134 coupled to the second side 118 of the housing 110. The cooling system 126 further includes a plurality of fins 142 exposed from the housing 110. A first portion of the electronics compartment 124 is coupled to a top surface 144 of the cooling system 126. A second portion of the electronics compartment 124 is coupled to a bottom surface 146 of the cooling system 126. The cooling system 126 is configured to facilitate heat transfer by dissipating heat from both the first portion of the electronics compartment 124 coupled to the top surface 144 of the cooling system 126 and the second portion coupled to the bottom surface 146 of the cooling system 126. In some embodiments, the electronics compartment 124 is positioned within the housing 110 such as to reduce air flow between the electronics compartment 124 and the air duct 128. Hence, the location of the electronics compartment 124 is such that air flow is lower than in a portion of the housing 110 that is not occupied (e.g., unused space within the housing 110, etc.).

FIG. 1 depicts a perspective view of a mobile power source system 10, according to an exemplary embodiment. In particular embodiments, the mobile power source system 10 is a mobile electric hybrid power source system 10. Referring to FIG. 1, the mobile power source system 10 is a mobile power source capable of using renewable energy resources to operate under harsh environmental conditions (e.g., fluctuating temperatures including temperature extremes, fluctuating humidity, rain, sand, dust, salt fog, etc.). For example, in some embodiments, the mobile power source system 10 has an operating temperature range from approximately −25° F. to 125° F. (−31.67° C. to 51.67° C.), inclusive. More particularly, the mobile power source system 10 may operate at temperatures from −25° F. to 95° F. (−31.67° C. to 35° C.), inclusive, at 4,000 feet (1219.2 meters) above sea level, at relative humidities with temperatures up to 125° F. (51.67° C.), inclusive, at sea level, and temperatures up to 95° F. (35° C.), inclusive, at altitudes ranging from 4,000 feet to 10,000 feet (1219.2 meters to 3048 meters). The mobile power source system 10 is also capable of operating below predetermined noise levels and mitigating electromagnetic interference (EMI). For example, in some embodiments, the mobile power source system 10 is configured to maintain a noise level below an audible threshold within an area extending approximately twenty meters, inclusive, away from and surrounding the mobile power source system 10. In some embodiments, the mobile power source system 10 is capable of mitigating EMI from electric fields over approximately 1 gigahertz, inclusive. For example, the mobile power source system 10 is capable of mitigating EMI in the range from approximately 0.01 GHz to 0.1 GHz, 0.5 GHz, 0.75 GHz, 1 GHz, 1.5 GHz, etc.

In addition to operating under harsh conditions, in some embodiments, the mobile power source system 10 is configured to meet mass and volume constraints. For example, the mobile power source system 10 is configured to have an internal spatial volume sufficient for enclosing internal components while remaining mobile (e.g., moveable, transportable, etc.). Further, because operational conditions may vary, the mass and volume limits may be adjusted, respectively. Accordingly, in some embodiments, the mobile power source system 10 is configured to be scalable and modular. By being both scalable and modular, the mobile power source system 10 is capable of operating under a wider range of operational requirements. Further still, in some embodiments, the mobile power source system 10 is coupled to a chassis 12 and/or a trailer 14 for further mobility.

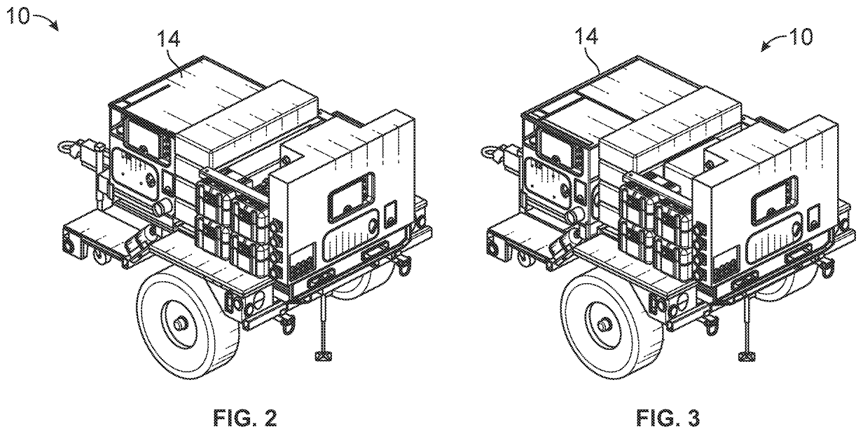

Referring to FIG. 1, the mobile power source system 10 includes a generator 16 (e.g., a power source, a power supply, etc.). The generator 16 is configured to provide power for operation of the mobile power source system 10. In some embodiments, the generator 16 is an Advanced Medium Mobile Power Source (AMMPS). Further still, because the mobile power source system 10 is scalable and modular, the generator 16 may be one of a 5 kilowatt (kW) AMMPS generator, a 10 kW AMMPS generator, or a 15 kW AMMPS generator, as seen in FIGS. 2-4. Although the above describes the mobile power source system 10 as having one generator 16, the mobile power source system 10 is not so limited and may be configured to connect or be coupled to a power grid (e.g., a utility grid, microgrid, etc.) in parallel with one or more additional generators 16.

FIG. 5 is a block diagram of the mobile power source system 10 including the electronics packaging assembly 100, according to an exemplary embodiment. Referring to FIG. 5, the mobile power source system 10 includes an energy storage system 18 (e.g., batteries, capacitors, etc.). In at least one exemplary embodiment, the energy storage system 18 is a 24-volt direct current (DC) battery.

Referring to FIG. 5, the mobile power source system 10 includes a secondary power source 20. The secondary power source 20 is a power source different from the generator 16 and is configured to supply power to the mobile power source system 10. Particularly, the secondary power source 20 is a renewable energy source which may not store power (e.g., a solar panel, a solar panel array, etc.).

Referring to FIG. 5, the mobile power source system 10 includes a system controller 22. The system controller 22 includes one or more processors and is configured be integrated with or in communication with various electronic devices of the mobile power source system 10. For example, in some embodiments, the system controller 22 may be a personal computer, server system, or other computational device. In some embodiments, the various electronic components may contribute to any of the operations described herein and may be used to program the system controller 22. In some embodiments, the system controller 22 may also include one or more additional processors, application-specific integrated circuits (ASICs), or circuitry that is designed to cause or assist with the electronics packaging assembly 100 in performing any of the steps, operations, processes, or methods described herein. In some embodiments, the system controller 20 is configured to store executable instructions that are executable by any of the circuits, processors, or hardware components.

Referring to FIG. 5, the mobile power source system 10 includes a system memory 24. In some embodiments, the system memory 24 may include a non-transitory computable readable medium that is coupled to the processor of the system controller 22 and stores one or more executable instructions that are configured to cause, when executed by the processor, the processor to perform or implement any of the steps, operations, processes, or methods described herein. The executable instructions may be of any type including applications, programs, services, tasks, scripts, libraries processes and/or firmware. The system controller 22 may implement any logic, functions or instructions stored in the system memory 24 to perform any of the operations described herein. In some embodiments, the system controller 22 includes the system memory 24.

Referring to FIG. 5, the mobile power source system 10 includes a power distribution system 26 (sometimes herein referred to as a power distribution unit (PDU)) (e.g., an electrical system, etc.). The power distribution system 26 is operatively coupled to, for example, the generator 16, the energy storage system 18, the secondary power source 20, the system controller 22, the system memory 24, and the electronics packaging assembly 100, discussed in further detail below. In some embodiments, the power distribution system 26 is configured to distribute power to an external source (e.g., by providing electrical power, etc.). The power distribution system 26 may also be configured to distribute power to each of the components of the mobile power source system 10.

Referring to FIG. 5, the mobile power source system 10 includes an electronics packaging assembly 100. The electronics packaging assembly 100 is configured to facilitate heat transfer from the mobile power source system 10, and more particularly, from electronic components housed within the electronics packaging assembly 100. In some embodiments, the electronics packaging assembly 100 is a microgrid AMMPS bi-directional electronics (“MABEL”) system made by Cummins, Inc. of Columbus, IN. The electronics packaging assembly 100 may be coupled (e.g., operatively coupled, electrically coupled, etc.) to, for example, the power distribution system via one or more contactors and/or connectors (e.g., a data connector 102, an AC connector 104, a DC connector 106, a DC contactor 108, etc.) for distributing power.

Like the mobile power source system 10, the electronics packaging assembly 100 is configured to operate under harsh environmental conditions (e.g., fluctuating temperatures, fluctuating humidity, rain, sand, dust, salt fog, etc.). For example, in some embodiments, the electronics packaging assembly 100 has an operating temperature range from approximately −25° F. to 125° F. (−31.67° C. to 51.67° C.), inclusive. More particularly, the electronics packaging assembly 100 may operate at temperatures from −25° F. to 95° F. (−31.67° C. to 35° C.), inclusive, at 4,000 feet (1219.2 meters) above sea level, at all relative humidity with temperatures up to 125° F. (51 to 67° C.), inclusive, at sea level, and temperatures up to 95° F. (35° C.), inclusive, at altitudes ranging from 4,000 feet to 10,000 feet (1219.2 meters to 3048 meters). The electronics packaging assembly 100 is also capable of operating below predetermined noise levels and mitigating electromagnetic interference. For example, in some embodiments, the electronics packaging assembly 100 is configured to maintain a noise level below an audible threshold within an area extending approximately twenty meters, inclusive, away from and surrounding the electronics packaging assembly 100. In some embodiments, the electronics packaging assembly 100 is capable of mitigating EMI from electric fields over approximately 1 gigahertz, inclusive. For example, the electronics packaging assembly 100 is capable of mitigating EMI in the range from approximately 0.01 GHz to 0.1 GHz, 0.5 GHz, 0.75 GHz, 1 GHz, 1.5 GHz, etc.

In addition to operating under harsh conditions, in some embodiments, the electronics packaging assembly 100 is configured to meet mass and volume constraints. For example, the electronics packaging assembly 100 is configured to have an internal spatial volume sufficient for enclosing internal components while remaining mobile. Further, because operational conditions may vary, the mass and volume limits may be adjusted, respectively. Accordingly, in some embodiments, the electronics packaging assembly 100 is configured to be scalable and modular. By being both scalable and modular, the electronics packaging assembly 100 is capable of operating under a wider range of operational requirements.

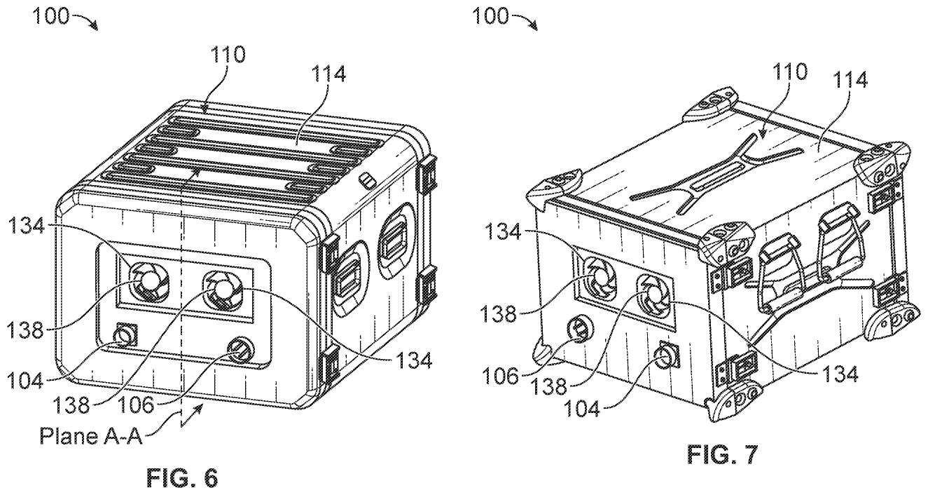

FIGS. 6 and 7 depict perspective views of the electronics packaging assembly 100 including a housing 110, according to exemplary embodiments. Referring to FIGS. 6 and 7, the electronics packaging assembly 100 includes a housing 110. The housing 110 (e.g., enclosure, compartment, etc.) encloses internal components of the electronics packaging assembly 100. In this way, the housing 110 protects the internal components from harsh environmental conditions. In some embodiments, the housing 110 is a weatherproof, ruggedized enclosure designed to withstand shock and vibration associated with operations in normal or harsh environments. In some embodiments, the housing 110 is made of a metal or a metallic material or alloy, which not only protects the internal components from the environment, but also mitigates EMI. In particular embodiments, the electronics packaging assembly 100 includes an EMI filter assembly 112 coupled to the housing 110 to provide further EMI resistance.

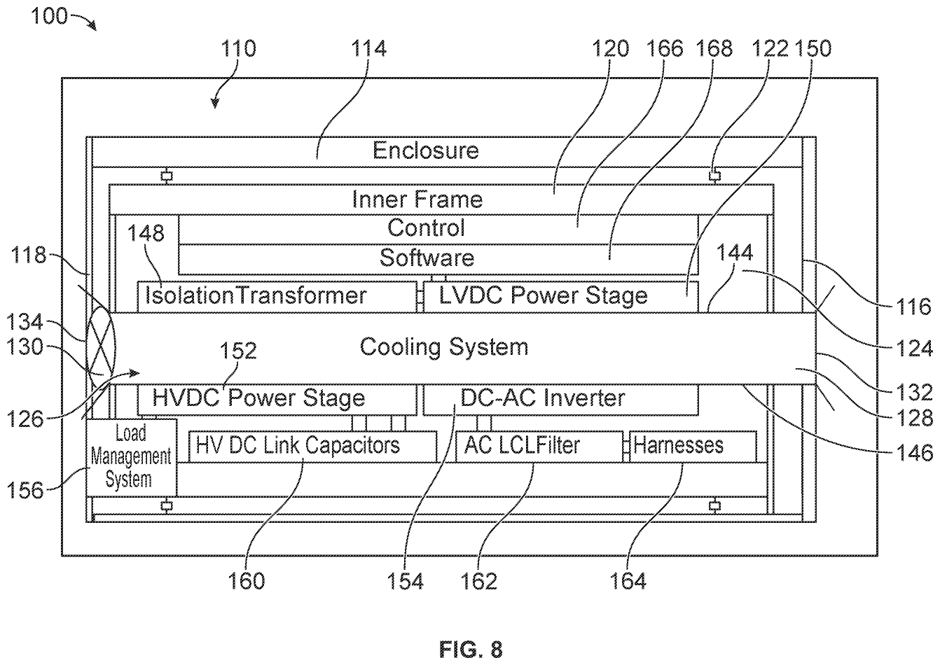

FIG. 8 is a schematic diagram of the electronics packaging assembly 100, according to an exemplary embodiment. Referring to FIGS. 6-8, in some embodiments, the housing 110 includes an outer frame 114. The outer frame 114 encloses the electronics packaging assembly 100 such as to define a first side 116 of the housing 110 and a second side 118 opposite the first side 116. The housing 110 also includes an inner frame 120 suspended within the outer frame 114. In this way, the inner frame 120 is separated (e.g., isolated, etc.) from the outer housing to further protect the internal components and reduce undesired vibration of the electronics packaging assembly 100. In some embodiments, the inner frame 120 is suspended within the outer frame 114 by a plurality of isolators 122 (e.g., harness, suspension system, etc.). Particularly, the plurality of isolators 122 are coupled to and disposed between the inner frame 120 and the outer frame 114 to suspend the inner frame 120 and reduce vibration of the electronics packaging assembly 100. Further, the housing 110 includes an electronics compartment 124 (e.g., module, assembly, system, etc.). The electronics compartment 124 is configured to house at least one electronic component therein, as discussed in further detail below. In at least one embodiment, the electronics compartment 124 is disposed within the inner frame 120. Accordingly, vibration of the electronics compartment 124 is reduced.

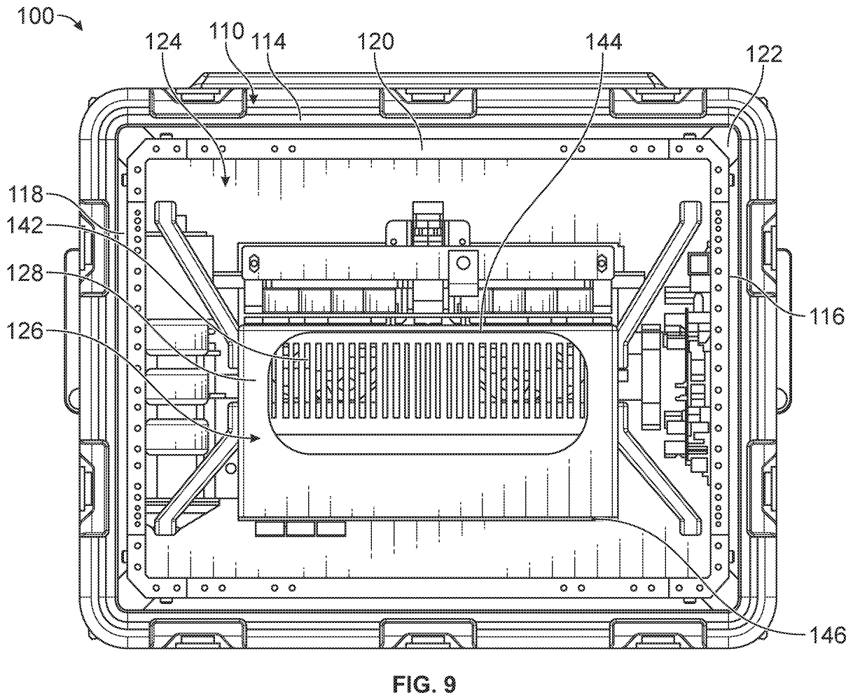

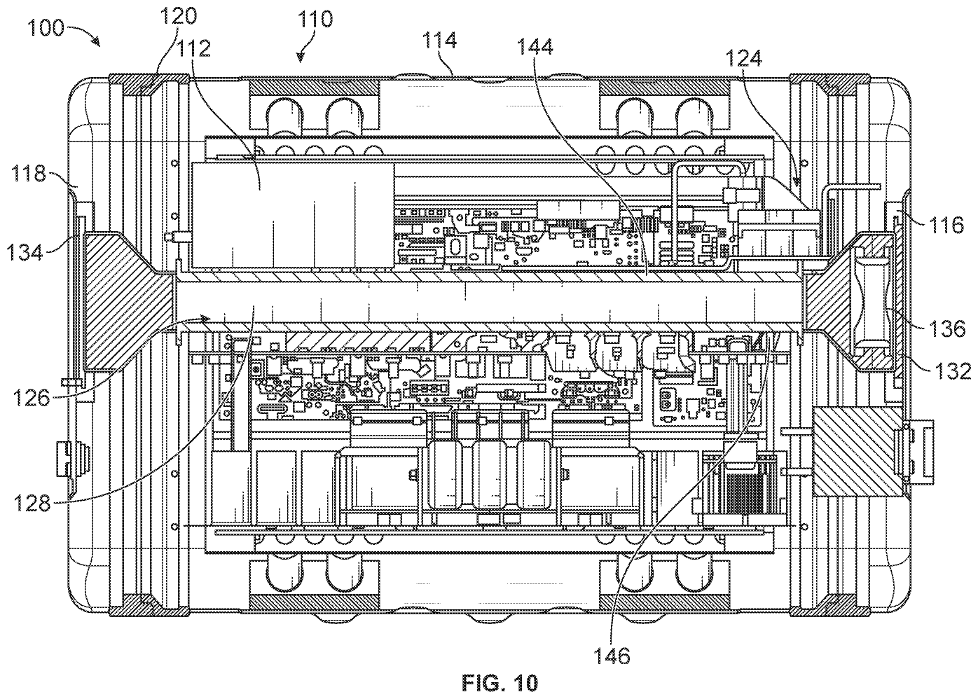

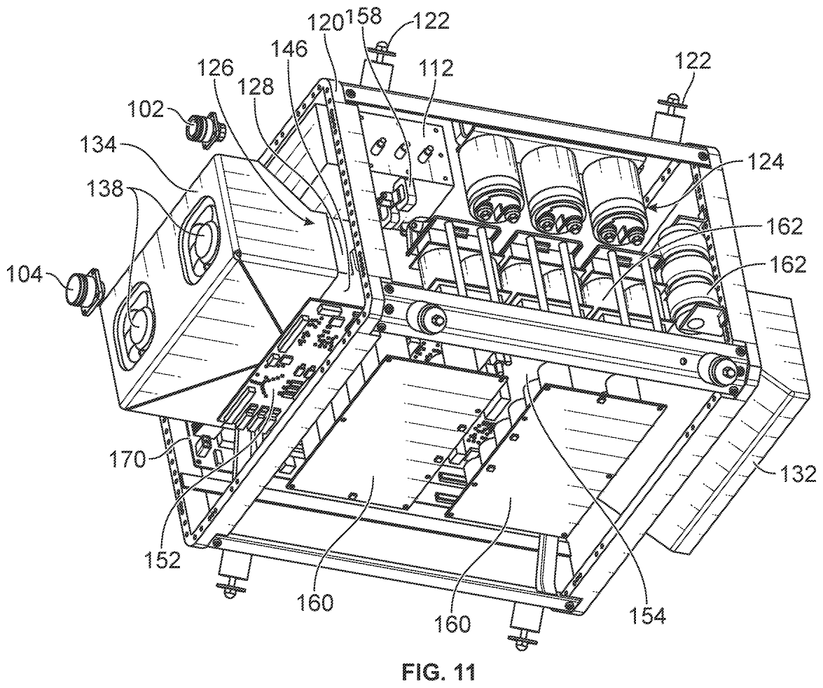

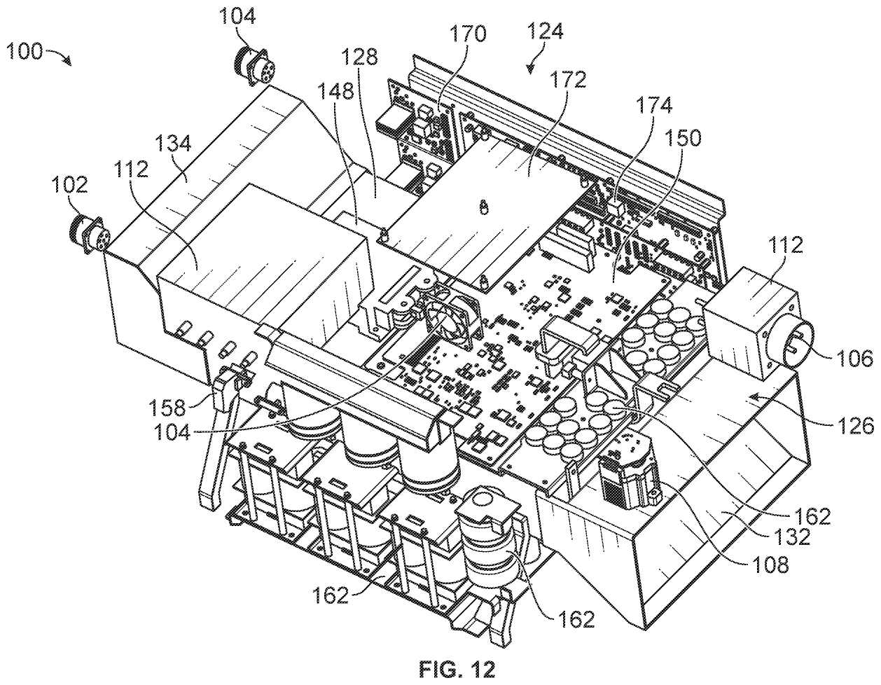

FIG. 9 is a cross-sectional side view of the electronics packaging assembly 100 taken along Plane A-A of FIG. 6, according to an exemplary embodiment. FIG. 10 is another cross-sectional side view of the electronics packaging assembly 100 taken along Plane A-A of FIG. 6, according to an exemplary embodiment. FIGS. 11 and 12 are a bottom and top perspective view, respectively, of the electronics packaging assembly 100 without the outer frame 114, according to an exemplary embodiment.

Referring to FIGS. 8-12, the electronics packaging assembly 100 includes a cooling system 126 (e.g., a cooling assembly, a heat sink, etc.). The cooling system 126 is configured to facilitate heat transfer of the electronics packaging assembly 100, and more particularly, dissipate heat from the electronics compartment 124. The cooling system 126 extends from the first side 116 of the housing 110 to the second side 118 of the housing 110. Specifically, the cooling system 126 includes an air duct 128 extending from the first side 116 of the housing 110 to the second side 118 of the housing 110. The air duct 128 defines a top surface 144, a bottom surface 146, and an air channel 130 (e.g., flow path, etc.) configured for air flow. The air channel 130 extends from the first side 116 to the second side 118 such that air flow is provided from either of the first side 116 or the second side 118 to the other of the first side 116 or the second side 118. In this way, air flow traveling through the air channel 130 may facilitate heat transfer. In some embodiments, the air duct 128 extends from the first side 116 to the second side 118 such that the air channel 130 and air flow therethrough are separated (e.g., sealed, isolated, etc.) from the electronics compartment 124 to reduce air flow between the electronics compartment 124 and the air duct 128. By positioning the air duct 128 and the electronics compartment 124 in this way, sensitive electronic components within the electronics compartment 124 may be protected from an external environment.

In some embodiments, the air duct 128 is further configured to facilitate heat transfer. For example, the air duct 128 may include a non-uniform surface configured to increase turbulence of the air flow as turbulent air flow is better suited for heat transfer compared to, for example, laminar flow. The air duct 128 may also be comprised of a copper heat pipe inlay, which may conduct heat from the air flow, thereby facilitating heat transfer. Further still, the air duct 128 many include thermally conductive encapsulants (e.g., thermally conductive filler, paste, gel, etc.) disposed on a surface of the air duct 128.

Referring to FIGS. 8-12, the cooling system 126 also includes an air duct inlet 132 (e.g., port, opening, etc.) and an air duct outlet 134 (e.g., port, opening, etc.). The air duct inlet 132 and the air duct outlet 134 are coupled (e.g., attached, fixed, welded, fastened, riveted, adhesively attached, bonded, pinned, etc.) to, respectively, one of the first side 116 or the second side 118. In at least one exemplary embodiment, the air duct inlet 132 is coupled to the first side 116 and the air duct outlet 134 is coupled to the second side 118. In this way, air flow enters the air duct inlet 132, flows through the air channel 130, and exits the air duct outlet 134 to facilitate heat transfer. In some embodiments, to facilitate air flow through the air channel 130, the cooling system 126 includes at least one of an inlet fan 136 and an outlet fan 138. The inlet fan 136 and the outlet fan 138 are disposed in the air duct inlet 132 and the air duct outlet 134, respectively, to provide air flow in a direction from the air duct inlet 132 towards the air duct outlet 134. Similarly, in some embodiments, the cooling system 126 includes a circulation fan 140. Unlike the inlet fan 136 and the outlet fan 138, the circulation fan 140 is disposed in the electronics compartment 124 to further dissipate heat from internal components housed within the electronics compartment 124.

Referring to FIGS. 8-12, the cooling system 126 further includes a plurality of fins 142 (e.g., vanes, etc.). The plurality of fins 142 are exposed from the housing 110 and are configured to facilitate heat transfer by radiating (e.g., dissipating, etc.) heat away from the electronics packaging assembly 100. For example, in some embodiments, the plurality of fins 142 remove heat from the air flow traveling through the air channel 130 and radiate the removed heat into the environment. In particular embodiments, each fin of the plurality of fins 142 includes a predetermined surface area and/or a predetermined orientation. For example, this predetermined surface area may be a surface area determined to maximize heat transfer.

As described above, the electronics packaging assembly 100 includes the electronics compartment 124. The electronics compartment 124 is disposed within the housing 110 and configured to house at least one electronic component therein. Because electronic components generate heat during operation, the electronics compartment 124 may be positioned to facilitate removal of the generated heat (e.g., facilitate heat transfer, etc.). For example, referring to FIG. 8, a first portion of the electronics compartment 124 is coupled to a top surface 144 of the cooling system 126 and second portion is coupled to a bottom surface 146 of the cooling system 126. Specifically, a portion of the electronics compartment 124 (the first portion) is coupled to the top surface 144 of the air duct 128 and a second portion is coupled to the bottom surface 146 of the air duct 128. Accordingly, the cooling system 126 facilitates heat transfer from both of the first portion of the electronics compartment 124 coupled to the top surface 144 of the cooling system 126 and the second portion coupled to the bottom surface 146 of the cooling system 126. In this way, the cooling system 126 facilitates heat transfer more efficiently compared to other systems which only facilitate heat transfer from one direction rather than more than one direction (e.g., bidirectional cooling, multidirectional cooling, etc.).

As described above, the at least one electronic component disposed within the electronics compartment 124 generates heat during operation. The generated heat may be dissipated by, for example, air flow traveling through the air duct 128. However, because the at least one electronic component may include one or more components sensitive to the environment, the electronics compartment 124 may be positioned to insulate the at least one electronic component. For example, in some embodiments, the electronics compartment 124 is positioned within the housing 110 such as to reduce air flow between the electronics compartment 124 and the air duct 128. By minimizing air flow between the electronics compartment 124 and the air duct 128, sensitive internal components of the electronics compartment 124 may be protected from the environment.

Referring to FIGS. 8-12, the electronics compartment 124 includes at least one electronic component disposed therein. As described above, a first portion of the electronics compartment 124 is coupled to the top surface 144 of the air duct 128 and a second portion is coupled to the bottom surface 146 of the air duct 128. Because these portions are coupled to the top surface 144 and the bottom surface 146, respectively, in some embodiments, it is advantageous to dispose electronic components on the top surface 144 or the bottom surface 146 which generate more heat compared to other electronic components. For example, in some embodiments, the portion of the electronics compartment 124 coupled to the top surface 144 of the cooling system 126 includes a high frequency direct current (HFDC) transformer 148 (e.g., an isolation transformer, etc.) and a low voltage direct current (LVDC) power stage 150 (e.g., a DC-DC LV power printed circuit board (PCB), etc.). In some embodiments, the other portion of the electronics compartment 124 coupled to the bottom surface 146 of the cooling system 126 includes a high voltage direct current (HVDC) power stage 152 (e.g., a MIPS1, etc.) and a direct current to alternating current (DC-AC) inverter 154 (e.g., a MIPS1, etc.). Because the HFDC transformer 148, the LVDC power stage 150, the HVDC power stage 152, and the DC-AC inverter 154 are coupled to the cooling system 126, the cooling system 126 more efficiently dissipates heat from the electronics compartment 124.

Although the above description includes a discussion of components of the electronics compartment 124, the components are not so limited. Referring to FIGS. 8-12, in addition to the HVDC power stage 152 and the DC-AC inverter 154, the electronics compartment 124 may also include a load management system 156. The load management system 156 is operatively coupled to the HVDC power stage 152 and is configured to manage a load of the electronics compartment 124. In some embodiments, the electronics compartment 124 includes a current sensor 158 to manage the load. Further, in some embodiments, the electronics compartment 124 includes HVDC link capacitors 160. The HVDC link capacitors 160 are operatively coupled to each of the HVDC power stage 152 and the DC-AC inverter 154. In some embodiments, the electronics compartment 124 also includes an AC inductor-capacitor-inductor (LCL) filter assembly 162 operatively coupled to the DC-AC inverter 154. Further, the AC LCL filter assembly 162 may be operatively coupled to a harness 164 (e.g., a wire harness, etc.).

Referring to FIGS. 8-12, in some embodiments, the electronics compartment 124 also includes a controller 166. In some embodiments, the controller 166 may include one or more processors, a memory 168, and an input/output interface. In some embodiments, the controller 166 may be integrated or in communication with various electronic devices. In some embodiments, the various electronic components may assist with any of the operations described herein and may be used to program the controller 166. The controller 166 may implement any logic, functions or instructions to perform any of the operations described herein. The controller 166 can include memory 168 of any type and form that is configured to store executable instructions that are executable by any of the circuits, processors, or hardware components. For example, the memory 168 (e.g., RAM, ROM, Flash Memory, hard disk storage, etc.) may store data and/or computer code for facilitating the various processes described herein. The memory 168 may be communicably connected to the processing circuitry to provide computer code or instructions for executing at least some of the processes described herein. The memory 168 may be or include tangible, non-transient volatile memory or non-volatile memory and may include database components, object code components, script components, or any other type of information structure for supporting the various activities and information structures described herein.

Further, the executable instructions may be of any type including applications, programs, services, tasks, scripts, libraries processes and/or firmware. In some embodiments, the memory 168 may include a non-transitory computable readable medium that is coupled to the processor and stores one or more executable instructions that are configured to cause, when executed by the processor, the processor to perform or implement any of the steps, operations, processes, or methods described herein. In at least one embodiment, the functions and operations of the controller 166 and the memory 168 may be realized by, for example, a power supply board 170, an interface board 172, a control and scaling board 174, or any combination thereof.

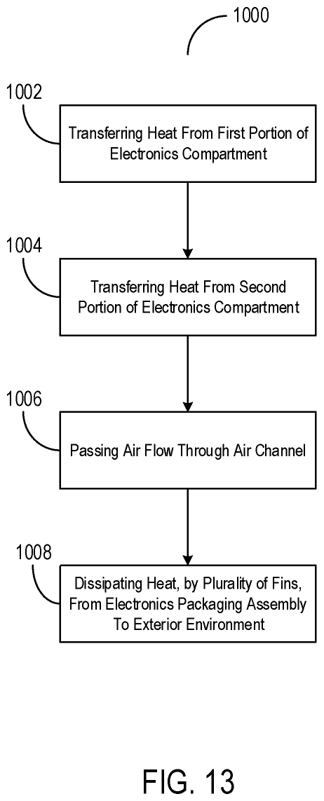

FIG. 13 illustrates a method 1000 (e.g., process, etc.) for cooling the electronics compartment 124 assembly using the cooling system 126 thereof. The operations described below are exemplary and non-limiting, and include optional operations which may be omitted in some embodiments. In brief overview, the method 1000 may include transferring heat, by a cooling system 126, from the first portion of the electronics compartment 124 coupled to the top surface 144 of the cooling system 126 to the cooling system 126 (step 1002). The method 1000 may include transferring heat, by the cooling system 126, from the second portion of the electronics compartment 124 coupled to the bottom surface 146 of the cooling system 126 to the cooling system 126 (step 1004). The method 1000 may include allowing, via the air duct 128, air flow through the air channel 130 (step 1006). The method 1000 may include dissipating heat, by the plurality of fins 142, from the electronics packaging assembly 100 to an exterior environment (step 1008).

For the method 1000, the electronics packaging assembly 100 may include a housing 110. The housing 110 may include an electronics compartment 124 configured to house at least one electronic component therein. The electronics packaging system 100 may include a cooling system 126 extending from a first side 116 of the housing 110 to a second side 118 of the housing 110 opposite the first side 116. The cooling system 126 may include an air duct 128 defining an air channel 130 for air flow, an air duct inlet 132 coupled to the first side 116 of the housing 110, an air duct outlet 134 coupled to the second side 118 of the housing 110, and a plurality of fins 142 exposed from the housing 110, a first portion of the electronics compartment 124 coupled to a top surface 144 of the cooling system 126, and a second portion coupled to a bottom surface 146 of the cooling system 126.

The method 1000 may include transferring heat, by the cooling system 126, from the first portion of the electronics compartment 124 coupled to the top surface 144 of the cooling system 126 to the cooling system 126 (step 1002). The top surface 144 may be defined by the air duct 128 of the cooling system 126, and may be thermally coupled with the first portion of the electronic component 124 to transfer heat through the cooling system 126. In this way, the cooling system 126 extracts heat generated by the electronic components of the electronics packaging assembly 100.

The method 1000 may include transferring heat, by the cooling system 126, from the second portion of the electronics compartment 124 coupled to the bottom surface 146 of the cooling system 126 to the cooling system 126 (step 1004). The bottom surface 146 may be defined by the air duct 128 of the air duct 128, and may be thermally coupled with the second portion of the electronic component 124 to transfer heat through the cooling system 126. Accordingly, the cooling system 126 is capable of facilitating heat transfer from more than one direction, thereby increasing cooling efficiency of the cooling system 126.

The method 1000 may include passing, via the air duct 128, air flow through the air channel 130 (step 1006). In this way, as the air flow travels through the air channel 130, the air flow also transfers heat from the electronics packaging assembly 100 to an external environment. In some embodiments, the air may be forced to flow through the air channel 130 using the inlet fan 136 or the outlet fan 138. The inlet fan 136 may be coupled with the air duct inlet 132. The outlet fan 138 may be coupled with the air duct outlet 134. In some embodiments, the air may be circulated within the electronics compartment 124 using the circulation fan that is disposed within the electronic compartment 124.

In some embodiments, the method 1000 includes generating, by at least one of an inlet fan 136 or an outlet fan 138 coupled to the air duct inlet 132 or the air duct outlet 134, respectively, the air flow through the air channel 130. In this way, the inlet fan 136 and/or the outlet fan 138 provide additional air flow through the air channel 130. In some embodiments, the method 1000 includes providing, by a circulation fan 140 disposed within the electronics compartment 124, air circulation within the electronics compartment 124. Therefore, even if air flow is reduced between the electronics compartment 124 and the air channel 130, the circulation fan 140 is able to facilitate heat transfer within the electronics compartment 124.

The method 1000 may include by dissipating heat, by the plurality of fins 142, from the electronics packaging assembly 100 to the exterior environment (step 1008). The plurality of fins 142 may be part of the cooling system 126, and may be exposed from the housing 110 to facilitating heat transfer by radiating (e.g., dissipating) the heat away from the electronic packing assembly 100. The fins 142 may increase a surface area for dissipating heat, thereby improving cooling efficiency of the cooling system 126.

In some embodiments, the method 1000 may include providing the air duct 128 with a non-uniform surface configured to increase turbulence of the air flow. At least a portion of the air duct 128 may have a non-uniform surface. Increased turbulence is generated along the portion of the air duct 128 provided with the non-uniform surface as compared to the air flow if the surface were instead uniform. Since turbulent air is associated with increased heat transfer, cooling efficiency may be improved.

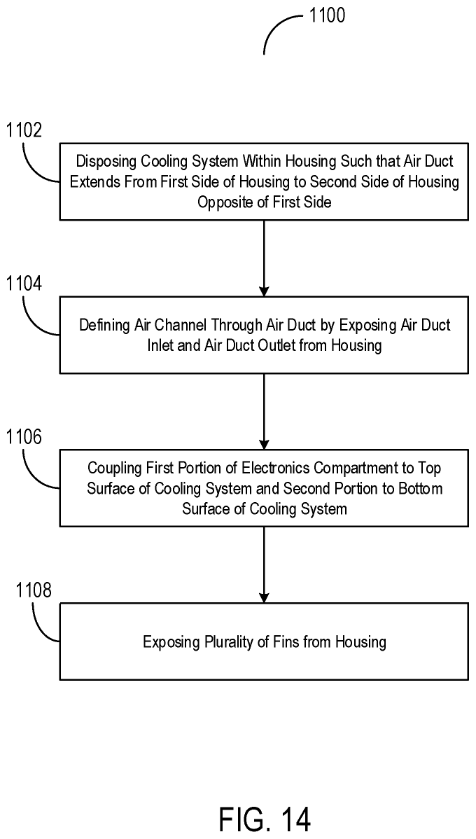

FIG. 14 illustrates a method 1100 (e.g., process, etc.) for manufacturing the electronics packaging assembly 100 having the cooling system 126. The operations described below are exemplary and non-limiting, and include operations which may be omitted in some embodiments. The method 1100 may be for manufacturing an electronics packaging assembly 100. In brief overview, the method 1100 includes disposing a cooling system 126 within the housing 110 such that the air duct 128 extends from a first side 116 of the housing 110 to a second side 118 of the housing 110 opposite the first side 116 (step 1102). The method 1100 may include defining an air channel 130 through the air duct 128 by exposing the air duct inlet 132 and the air duct outlet 134 from the housing 110 (step 1104). The method 1100 may include coupling a first portion of the electronics compartment 124 to a top surface 144 of the cooling system 126 and a second portion to a bottom surface 146 of the cooling system 126. The method 1100 may include positioning the electronics compartment 124 within the housing 110 such that air flow is reduced between the air channel 130 and the electronics compartment 124 (step 1106). The method 1100 may include exposing the plurality of fins 142 from the housing 110 (step 1108).

In further detail, the method 1100 may include disposing a cooling system 126 within the housing 110 such that the air duct 128 extends from a first side 116 of the housing 110 to a second side 118 of the housing 110 opposite the first side 116 (step 1102). The housing 110 may define a volume within which one or more components of the cooling system 126 may be disposed. The housing 110 may include an electronics compartment 124 configured to house at least one electronic component therein. The air duct 128 may extend from the first side 116 to the second side 118 of the housing 110.

The method 1100 may include defining an air channel 130 through the air duct 128 by exposing the air duct inlet 132 and the air duct outlet 134 from the housing 110 (step 1104). The air duct 128 may extend from the first side 116 to the second side 118 such that the air channel 130 and air flow therethrough are separated (e.g., sealed, isolated, etc.) from an electronics compartment 124 to reduce air flow between the electronics compartment 124 and the air duct 128. Accordingly, air flow may be allowed to be provided through the air channel 130 to facilitate heat transfer.

The method 1100 may include coupling the first portion of the electronics compartment 124 to a top surface 144 of the cooling system 126 and the second portion to a bottom surface 146 of the cooling system 126 (step 1106). The first portion of the electronics compartments 124 may be thermally or mechanically coupled (e.g., contact) with the top surface 144 and the bottom surface 146 of the cooling system 126. Accordingly, the cooling system 126 is capable of facilitating heat transfer from more than one direction, thereby increasing cooling efficiency of the cooling system 126.

The method 1100 may include exposing the plurality of fins 142 from the housing 110 (step 1108). The plurality of fins 142 may be exposed from an interior to an exterior of the housing 110 to facilitate heat transfer by radiating or dissipating heat away from the electronics packaging assembly 100. Because the fins 142 are exposed from the housing 110, the plurality of fins 142 are disposed to dissipate heat from the electronics compartment 124 into the external environment.

In some embodiments, the method 1100 may include coupling an inlet fan 136 with the air duct inlet 132. The method 1100 may include coupling an outlet fan 138 with the air duct outlet 134. In this way, the inlet fan 136 and/or the outlet fan 138 provide additional air flow through the air channel 130 to facilitate the transfer of heat. In some embodiments, the method 1100 includes disposing a circulation fan 140 within the electronics compartment 124. The circulation fan 140 may be disposed in the electronics compartment 124 to further dissipate heat from internal components housed within the electronics compartment 124. Therefore, even if air flow is reduced between the electronics compartment 124 and the air channel 130, the circulation fan 140 is able to facilitate heat transfer within the electronics compartment 124.

In some embodiments, the method 1100 includes adjusting a direct current power supply by a direct current transformer and providing a first voltage direct current power stage in the first portion of the electronics compartment. The method 1100 may include generating a second voltage direct current power stage higher in voltage (e.g., configured to operate for higher voltage power, etc.) than the first voltage direct current power stage. In some embodiments, a high frequency direct current transformer 148 and a low voltage direct current power stage 150 in the first portion of the electronics compartment 124 coupled to the top surface 144 of the cooling system 126. The method 1100 may include providing a high voltage direct current power stage 152 and converting a direct current to alternating current by an inverter 154 in the second portion of the electronics compartment 124 coupled to the bottom surface 146 of the cooling system 126. Owing at least in part to the coupling of the electronic compartment 124 to the cooling system 126, the cooling system 126 is able to more efficiently facilitate heat transfer. In particular, the cooling system 126 is configured to promote heat dissipation from the electronic components in the electronics compartment 124 due to the coupling of the electronics compartment 124 to the cooling system 126.

In some embodiments, the method 1100 may include coupling an electromagnetic interference (EMI) filter assembly 112 to the housing 110, the EMI filter assembly 112 being configured to resist electromagnetic interference. In some embodiments, the method 1100 may include selecting a desired power output and a desired mobility amount of the electronics packaging assembly 100. In this way, the electronics packaging assembly 100 may be manufactured to be scalable and modular. For example, if the electronics packaging assembly 100 is expected to be frequently moved and transported, a generator having a smaller volume compared to another generator may be selected to increase mobility.

While this specification contains various implementation details, these should not be construed as limitations on the scope of what may be claimed but rather as descriptions of features specific to particular implementations. Certain features described in this specification in the context of separate implementations can also be implemented in combination in a single implementation. Conversely, various features described in the context of a single implementation can also be implemented in multiple implementations separately or in any suitable subcombination. Moreover, although features may be described as acting in certain combinations and even initially claimed as such, one or more features from a claimed combination can, in some cases, be excised from the combination, and the claimed combination may be directed to a subcombination or variation of a subcombination.

As utilized herein, the terms “substantially” and “generally,” and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the appended claims.

The term “coupled” and the like, as used herein, mean the joining of two components directly or indirectly to one another. Such joining may be stationary (e.g., permanent) or moveable (e.g., removable or releasable). Such joining may be achieved with the two components or the two components and any additional intermediate components being integrally formed as a single unitary body with one another, with the two components, or with the two components and any additional intermediate components being attached to one another. For example, an air inlet and an air outlet are, in some embodiments, connectable via one or more intermediate conduit sections such that the air inlet and the air outlet are coupled together.

The terms “fluidly coupled to” and the like, as used herein, mean the two components or objects have a pathway formed between the two components or objects in which a fluid, such as air, reductant, an air-reductant mixture, coolant or other liquids and/or gasses, may flow, either with or without intervening components or objects. Examples of fluid couplings or configurations for enabling fluid communication may include piping, channel 130s, or any other suitable components for enabling the flow of a fluid from one component or object to another.

Also, the term “or” is used, in the context of a list of elements, in its inclusive sense (and not in its exclusive sense) so that when used to connect a list of elements, the term “or” means one, some, or all of the elements in the list. Conjunctive language such as the phrase “at least one of X, Y, and Z,” unless specifically stated otherwise, is otherwise understood with the context as used in general to convey that an item, term, etc. may be either X, Y, Z, X and Y, X and Z, Y and Z, or X, Y, and Z (i.e., any combination of X, Y, and Z). Thus, such conjunctive language is not generally intended to imply that certain embodiments require at least one of X, at least one of Y, and at least one of Z to each be present, unless otherwise indicated.

References herein to the positions of elements (e.g., “top,” “bottom,” “above,” “below”) are merely used to describe the orientation of various elements in the FIGURES. It should be noted that the orientation of various elements may differ according to other exemplary embodiments, and that such variations are intended to be encompassed by the present disclosure.

Additionally, the use of ranges of values herein are inclusive of their maximum values and minimum values unless otherwise indicated. The terms “about” or “approximately” in connection with a given numerical value encompass values within at least 5% of the stated value, including, e.g., 0.5%, 1% and 2.5% of the stated value.

It is important to note that the construction and arrangement of the various systems and the operations according to various techniques shown in the various example implementations is illustrative only and not restrictive in character. All changes and modifications that come within the spirit and/or scope of the described implementations are desired to be protected. It should be understood that some features may be omitted in certain embodiments whereas additional features may be present, and various modifications to any of the foregoing embodiments are feasible and fall within the scope of the disclosure, the scope being defined by the claims that follow.

What is claimed is:

1. An electronics packaging assembly configured to facilitate heat transfer, the electronics packaging assembly comprising:
a housing including an electronics compartment configured to house at least one electronic component therein; and
a cooling system extending from a first side of the housing to a second side of the housing opposite the first side, the cooling system comprising:
an air duct defining an air channel for air flow,
an air duct inlet coupled to the first side of the housing,
an air duct outlet coupled to the second side of the housing, and
a plurality of fins exposed from the housing,
the electronics compartment being configured such that a first portion of the electronics compartment is coupled to a top surface of the cooling system and a second portion of the electronics compartment is coupled to a bottom surface of the cooling system, and the cooling system being configured to facilitate heat transfer by dissipating heat from both the first portion of the electronics compartment coupled to the top surface of the cooling system and the second portion coupled to the bottom surface of the cooling system.

2. The electronics packaging assembly according to claim 1, wherein
the housing includes an outer frame and an inner frame suspended within the outer frame,
the air duct inlet is coupled to the outer frame at the first side;
the air duct outlet is coupled to the outer frame at the second side, and
at least a portion of the electronics compartment is disposed within the inner frame.

3. The electronics packaging assembly according to claim 2, further comprising a plurality of isolators disposed between the inner frame and the outer frame configured to suspend the inner frame within the outer frame and to reduce vibration of the electronics packaging assembly.

4. The electronics packaging assembly according to claim 1, wherein at least one of the air duct inlet or the air duct outlet includes an inlet fan or an outlet fan, respectively, to allow air flow through the air channel.

5. The electronics packaging assembly according to claim 1, wherein the cooling system further comprises a circulation fan disposed within the electronics compartment.

6. The electronics packaging assembly according to claim 1, wherein an operating temperature range of the electronics packaging assembly is approximately −25° F. to 125° F., inclusive.

7. The electronics packaging assembly according to claim 1, wherein a noise level of the electronics packaging assembly is maintained below an audible threshold within an area extending approximately twenty meters away from and surrounding the electronics packaging assembly.

8. The electronics packaging assembly according to claim 1, wherein the air duct includes a non-uniform surface configured to increase turbulence of the air flow.

9. The electronics packaging assembly according to claim 1, wherein the air duct is a copper heat pipe inlay.

10. The electronics packaging assembly according to claim 1, wherein the cooling system includes thermally conductive encapsulants disposed on a surface of the air duct.

11. The electronics packaging assembly according to claim 1, wherein
the first portion of the electronics compartment includes a direct current transformer and a first voltage direct current power stage, and
the second portion of the electronics compartment includes a second direct current power stage that is higher in voltage than the first voltage direct current power stage and a direct current to alternating current inverter.

12. A method for cooling an electronics packaging assembly, the electronics packaging assembly including a housing including an electronics compartment configured to house at least one electronic component therein; and a cooling system extending from a first side of the housing to a second side of the housing opposite the first side, the cooling system including an air duct defining an air channel for air flow, an air duct inlet coupled to the first side of the housing, an air duct outlet coupled to the second side of the housing, and a plurality of fins exposed from the housing, a first portion of the electronics compartment coupled to a top surface of the cooling system and a second portion coupled to a bottom surface of the cooling system, the method comprising:
transferring heat from the first portion of the electronics compartment to the cooling system;
transferring heat from the second portion of the electronics compartment coupled to the bottom surface of the cooling system to the cooling system;
passing air flow through the air channel; and
dissipating heat, by the plurality of fins, from the electronics packaging assembly to an exterior environment via the plurality of fins.

13. The method according to claim 12, wherein the passing comprises forcing air to flow through the air channel, using at least one of an inlet fan or an outlet fan coupled to the air duct inlet or the air duct outlet, respectively.

14. The method according to claim 12, wherein the passing comprises circulating air within the electronics compartment using a circulation fan disposed within the electronics compartments.

15. The method according to claim 12, further comprising increasing turbulence of the air flow along at least a portion of the air duct.

16. A method for manufacturing an electronics packaging assembly, the electronics packaging assembly including a housing including an electronics compartment configured to house at least one electronic component therein; and a cooling system including an air duct, an air duct inlet, an air duct outlet, and a plurality of fins, the method comprising:
disposing the cooling system within the housing such that the air duct extends from a first side of the housing to a second side of the housing opposite the first side;
exposing the air duct inlet and the air duct outlet from the housing to define an air channel through the air duct;
coupling a first portion of the electronics compartment to a top surface of the cooling system and a second portion to a bottom surface of the cooling system; and
exposing the plurality of fins from the housing.

17. The method according to claim 16, further comprising:
coupling at least one of an inlet fan or an outlet fan to at least one of the air duct inlet or the air duct outlet, respectively.

18. The method according to claim 16, further comprising:
disposing a circulation fan within the electronics compartment to provide air circulation within the electronics compartment.

19. The method according to claim 16, further comprising:
adjusting a direct current power supply by a direct current transformer and providing a first voltage direct current power stage in the first portion of the electronics compartment coupled to the top surface of the cooling system; and
generating a second voltage direct current power stage higher in voltage than the first voltage direct current power stage and converting a direct current to alternating current by an inverter in the second portion of the electronics compartment coupled to the bottom surface of the cooling system.

20. The method according to claim 16, further comprising:
coupling an electromagnetic interference (EMI) filter assembly to the housing, the EMI filter assembly being configured to resist electromagnetic interference.
